(19) United States
(12) Patent Application Publication
(10) Pub. No.: US 2023/0187178 A1
(43) Pub. Date: Jun. 15, 2023

(54) GAS SUPPLY MODULE AND SUBSTRATE PROCESSING APPARATUS USING THE SAME

(71) Applicant: SAMSUNG ELECTRONICS CO., LTD., SUWON-SI (KR)

(72) Inventors: Youngil KANG, Hwaseong-si (KR); Byeongsang KIM, Hwaseong-si (KR); Jongmu KIM, Suwon-si (KR); Yongbeom PARK, Yongin-si (KR); Dougyong SUNG, Seoul (KR); Yunjae LEE, Suwon-si (KR); Seugkyu LIM, Uiwang-si (KR); Kyuhee HAN, Seongnam-si (KR)

(21) Appl. No.: 17/993,055

(22) Filed: Nov. 23, 2022

(30) Foreign Application Priority Data
Dec. 10, 2021 (KR) 10-2021-0176818

(51) Int. Cl. H01J 37/32

(52) U.S. Cl. CPC H01J 37/3244; H01J 2237/335; H01J 37/32724

(57) ABSTRACT

A substrate processing apparatus includes: a process chamber; a substrate support structure disposed at a lower portion of the process chamber and configured to accommodate a substrate; and a gas supply module disposed at an upper portion of the process chamber and supplying a process gas to the substrate, wherein the gas supply module includes a showerhead that includes: a first showerhead body including a plurality of injection ports configured to transfer gas transferred from a gas inlet into the process chamber; and a coating layer covering the first showerhead body and including aluminum fluoride, wherein the first showerhead body includes a metal matrix composite (MMC).

### CROSS-REFERENCE TO RELATED APPLICATION

This application claims the priority under 35 USC 119(a) to Korean Patent Application No. 10-2021-0176818 filed on Dec. 10, 2021 in the Korean Intellectual Property Office, the disclosure of which is incorporated by reference herein in its entirety.

### TECHNICAL FIELD

The present inventive concept relates to a gas supply module and a substrate processing apparatus including the same.

### DISCUSSION OF THE RELATED ART

Among processes for manufacturing a semiconductor device, deposition or etching is performed using a substrate processing apparatus using plasma. Recently, in accordance with an increase in diameter or size of a semiconductor wafer and an increase in integration of a semiconductor device, difficulty in deposition and etching has increased.

### SUMMARY

An exemplary embodiment of the present inventive concept may provide a gas supply module having increased thickness distribution in deposition and increased reliability, and a substrate processing apparatus including the same.

According to an exemplary embodiment of the present inventive concept, a substrate processing apparatus includes: a process chamber; a substrate support structure disposed at a lower portion of the process chamber and configured to accommodate a substrate; and a gas supply module disposed at an upper portion of the process chamber and supplying a process gas to the substrate, wherein the gas supply module includes a showerhead that includes: a first showerhead body including a plurality of injection ports configured to transfer gas transferred from a gas inlet into the process chamber; and a coating layer covering the first showerhead body and including aluminum fluoride, wherein the first showerhead body includes a metal matrix composite (MMC).

According to an exemplary embodiment of the present inventive concept, a substrate processing apparatus includes: a process chamber; a substrate support structure disposed at a first portion of the process chamber and configured to accommodate a substrate; and a gas supply module disposed at a second portion of the process chamber and supplying a process gas to the substrate, wherein the gas supply module includes: a showerhead including a showerhead body and a coating layer, wherein the showerhead body includes a gas inlet and a plurality of injection ports configured to transfer the process gas transferred from the gas inlet into the process chamber, and wherein the coating layer covers the showerhead body; an insulating member disposed between the showerhead and the process chamber; and a temperature control unit controlling a temperature of the gas supply module, the showerhead has a first region in which the plurality of injection ports are disposed and a second region extending from the first region, the insulating member is disposed on the second region and separates the second region from the process chamber, and the showerhead body includes a metal matrix composite (MMC).

According to an exemplary embodiment of the present inventive concept, a substrate processing apparatus comprises: a process chamber, a substrate support structure disposed at a lower portion of the process chamber and configured to accommodate a substrate, and a gas supply module disposed at an upper portion of the process chamber and supplying a process gas to the substrate, wherein the gas supply module includes: a showerhead including a plurality of injection ports configured to transfer gas, which is transferred from a gas inlet, into a process chamber; and a temperature control unit controlling a temperature of the showerhead, wherein the showerhead includes a showerhead body and a coating layer, wherein the showerhead body includes a metal matrix composite (MMC), and the coating layer covers the showerhead body and includes aluminum fluoride.

### BRIEF DESCRIPTION OF DRAWINGS

The above and other features of the present inventive concept will become more apparent by describing in detail example embodiments thereof, with reference to the accompanying drawings, in which:

FIG. 1 is a schematic cross-sectional view of a substrate processing apparatus according to an exemplary embodiment of the present inventive concept;

FIG. 2 is a schematic plan view of a gas supply module according to an exemplary embodiment of the present inventive concept;

FIG. 3 is a schematic cross-sectional view illustrating the gas supply module and a portion of a process chamber adjacent thereto according to an exemplary embodiment of the present inventive concept;

FIG. 4 is a graph for describing a temperature change of a susceptor while the substrate processing apparatus, according to an exemplary embodiment of the present inventive concept, performs cleaning;

FIGS. 5A and 5B are partially enlarged cross-sectional views of modified examples of the gas supply module according to an exemplary embodiment of the present inventive concept of FIG. 3;

FIG. 6 is a schematic cross-sectional view illustrating a gas supply module and a portion of a process chamber adjacent thereto according to an exemplary embodiment of the present inventive concept;

FIG. 7 is a schematic cross-sectional view illustrating a gas supply module according to an exemplary embodiment of the present inventive concept; and

FIGS. 8A and 8B are partially enlarged cross-sectional views of modified examples of the gas supply module, according to an exemplary embodiment of the present inventive concept, of FIG. 7.

### DETAILED DESCRIPTION OF THE EMBODIMENTS

Hereinafter, exemplary embodiments of the present inventive concept will now be described with reference to the accompanying drawings.

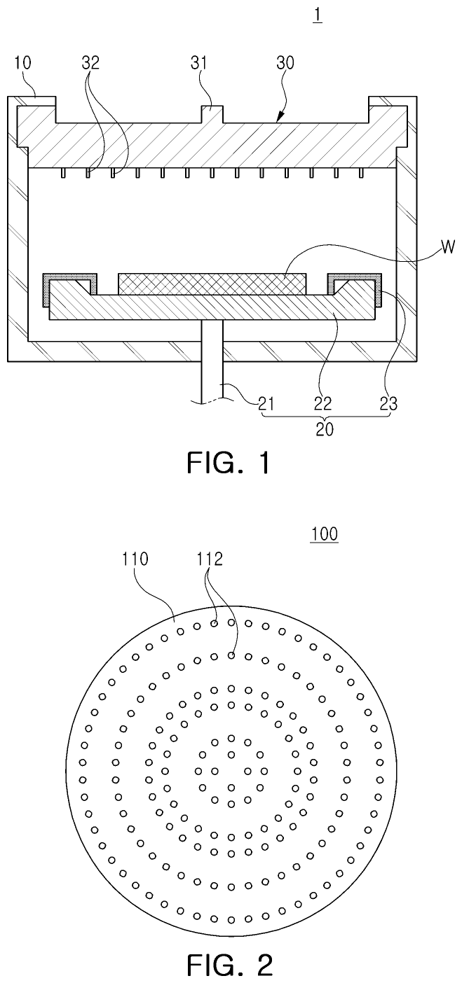

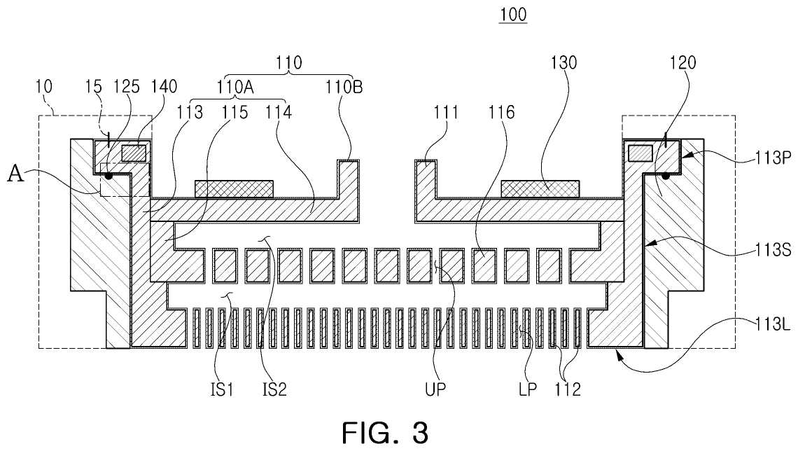

FIG. 1 is a schematic cross-sectional view of a substrate processing apparatus 1 according to an exemplary embodiment of the present inventive concept. FIG. 2 is a schematic plan view of a gas supply module 100 according to an exemplary embodiment of the present inventive concept. FIG. 3 is a schematic cross-sectional view illustrating the gas supply module 100 and a portion of a process chamber 10 adjacent thereto according to an exemplary embodiment of the present inventive concept.

Referring to FIG. 1, the substrate processing apparatus 1 may include a process chamber 10, a substrate support structure 20, and a showerhead structure 30.

The process chamber 10 may provide a space sealed from the outside for a substrate W, and may provide a sealed space in which a process is performed on the substrate W. The process may include, for example, at least one of deposition, etching, or cleaning. The substrate W may be a semiconductor wafer. The process chamber 10 may include a metal material such as aluminum (Al). According to an exemplary embodiment of the present inventive concept, the process chamber 10 may include a substrate passage through which the substrate W is loaded or unloaded. The substrate passage may include a chamber penetrating portion that penetrates through a portion of the process chamber 10. The substrate passage may further include a door unit that closes and opens the chamber penetrating portion. However, the shape of the substrate passage through which the substrate W enters and exits is not limited thereto, and may be variously changed.

The substrate support structure 20 may include a vertical support 21, a horizontal support 22 disposed on the vertical support 21, and a ring 23. The vertical support 21 may extend while penetrating through the process chamber 10. The vertical support 21 may be moved up and down by a separate driving device. For example, a micromotor or an actuator may be used to move the vertical support 21. The horizontal support 22 may be disposed on the vertical support 21 in the process chamber 10, and may be fixed by the vertical support 21. The horizontal support 22 may have an upper surface on which the substrate W is loaded. The horizontal support 22 may include a susceptor including a heating pattern. The heating pattern may heat the susceptor by using power supplied from the outside. The susceptor may be formed of, for example, a ceramic material such as aluminum nitride (AlN) or aluminum oxide (Al₂O₃). According to an exemplary embodiment of the present inventive concept, the susceptor may react with fluorine gas used for cleaning to form byproducts including aluminum fluoride (AlF). The byproducts may be attached to the process chamber 10 or the showerhead structure 30 and may impair performance of the substrate processing apparatus 1. Accordingly, a cleaning process to remove the byproducts from the substrate processing apparatus 1 may be performed after processes such as deposition and cleaning for maintenance of the substrate processing apparatus 1. The ring 23 may control a flow of gas in the process chamber 10 to adjust the amount of gas to be supplied to the substrate W or the horizontal support 22. The ring 23 may surround an edge region of the upper surface and a portion of a side surface of the horizontal support 22, but present inventive concept is not limited thereto. For example, the ring 23 may be disposed on an edge region of the horizontal support 22. The ring 23 may be formed of a ceramic material such as aluminum nitride (AlN).

The substrate W may be disposed on the horizontal support 22 in the process chamber 10, and various processes such as chemical vapor deposition (CVD) may be performed on the substrate W.

The showerhead structure 30 may be spaced apart from the horizontal support 22 and disposed above the horizontal support 22. The showerhead structure 30 may face the horizontal support 22. The showerhead structure 30 may adjust uniformity and distribution of process gas injected to the substrate W in the process chamber 10 to control thickness distribution and film quality characteristics of a deposited material. According to an exemplary embodiment of the present inventive concept, the showerhead structure 30 may be connected to a power supply device and/or a ground electrode to generate plasma. The showerhead structure 30 may include a gas inlet 31 through which the process gas is introduced and a plurality of injection ports 32 through which the introduced process gas is discharged. According to an exemplary embodiment of the present inventive concept, the showerhead structure 30 may be disposed at an upper portion of the process chamber 10, and may cover an upper portion of the process chamber 10 to provide a sealed space, in which the process is performed together, with the process chamber 10, but the shapes of the process chamber 10 and the showerhead structure 30 are not limited thereto. In addition, the process chamber 10 may provide a sealed space, and the gas inlet 31 may penetrate through the process chamber 10. Further, the remaining portion of the showerhead structure 30 may be disposed inside the process chamber 10. In the present specification, the showerhead structure 30 may also be referred to as a “gas supply module”, and a detailed structure thereof will be described below.

Referring to FIGS. 2 and 3, the gas supply module 100 may include a showerhead 110, an insulating member 120, and a temperature control unit 130.

The showerhead 110 may include a showerhead body 110A and a coating layer 110B covering the showerhead body 110A. The showerhead body 110A may include a metal matrix composite (MMC). According to an exemplary embodiment of the present inventive concept, the showerhead body 110A may include a matrix metal, such as aluminum (Al), and a ceramic filler such as silicon carbide (SiC). The coating layer 110B may conformally cover a surface of the showerhead body 110A. The coating layer 110B may include aluminum fluoride (AlF). According to an exemplary embodiment of the present inventive concept, the coating layer 110B may further include a material having etch resistance, such as yttrium oxide (Y₂O₃). According to an exemplary embodiment of the present inventive concept, the coating layer 110B may further include two or more materials having etch resistance.

According to an exemplary embodiment of the present inventive concept, the showerhead body 110A may include a lower structure 113, an upper structure 114, and a blocker plate 115. The showerhead body 110A may have an internal space formed by the lower structure 113 and the upper structure 114. The internal space may be divided into a first internal space IS1 and a second internal space IS2 by the blocker plate 115. For example, the first internal space IS1 may be on the lower side of the blocker plate 115, and the second internal space IS2 may be on the upper side of the blocker plate 115. The second internal space IS2 may be disposed above the first internal space IS1. For example, the first internal space IS1 may be formed below the blocker plate 115, and the second internal space IS2 may be formed above the blocker plate 115. The blocker plate 115 may include a plurality of internal gas supply units 116 for transferring the process gas of the second internal space IS2 to the first internal space IS1. However, according to an exemplary embodiment of the present inventive concept, the showerhead body 110A does not have to include the blocker plate 115.

According to an exemplary embodiment of the present inventive concept, the lower structure 113 may have a lower region 113L, a side region 113S, and a protrusion 113P. The side region 113S may extend from the lower region 113L. For example, the side region 113S may extend in a direction substantially perpendicular to the lower region 113L, for example, in a z-direction. The protrusion 113P may protrude from the side region 113S toward the process chamber 10. The upper structure 114 may have a plate structure that is in contact with a portion of an inner surface of the lower structure 113. For example, the upper structure 114 overlaps the second internal space IS2. However, the shapes of the lower structure 113 and the upper structure 114 are not limited thereto.

The showerhead body 110A may further include a gas inlet 111, through which the process gas is introduced, and a plurality of injection ports 112, through which the introduced process gas is supplied to the process chamber 10. According to an exemplary embodiment of the present inventive concept, the gas inlet 111 may be a member connected to the upper structure 114 to introduce the process gas to a space in the upper structure 114, and the plurality of injection ports 112 may be members for supplying the process gas to the process chamber 10 through a space penetrating through the lower region 113L of the lower structure 113. For example, the gas inlet 111 may be a tube or a pipe; however, the present inventive concept is not limited thereto. For example, the plurality of injection ports 112 may be a tube or a pipe; however, the present inventive concept is not limited thereto. The process gas may include one or more source gases. The plurality of injection ports 112 may uniformly apply the process gas to the substrate W to control thickness distribution of the deposited material.

According to an exemplary embodiment of the present inventive concept, each of the plurality of injection ports 112 may have a lower penetrating portion LP penetrating through the showerhead body 110A. The lower penetrating portion LP may be a circular hole penetrating through the lower region 113L of the lower structure 113, and the plurality of injection ports 112 may be arranged at predetermined intervals along a circumference of a circle having a constant diameter in the showerhead body 110A. However, the shape of the lower penetrating portion LP and the arrangement relationship of the plurality of injection ports 112 are not limited thereto and may be variously changed.

According to an exemplary embodiment of the present inventive concept, each of the plurality of internal gas supply units 116 of the blocker plate 115 may have an upper penetrating portion UP penetrating through the blocker plate 115. The upper penetrating portion UP may be a circular hole, but is not limited thereto. According to an exemplary embodiment of the present inventive concept, the number of the plurality of injection ports 112 per unit area may be different from the number of the plurality of internal gas supply units 116 per unit area. For example, the number of the plurality of injection ports 112 per unit area may be larger than the number of the plurality of internal gas supply units 116 per unit area, and a diameter of the upper penetrating portion UP may be larger than a diameter of the lower penetrating portion LP.

The coating layer 110B may cover an inner side of the lower penetrating portion LP of each of the plurality of injection ports 112. For example, the coating layer 110B may conformally cover the inside of the hole penetrating through the lower region 113L of the showerhead body 110A. According to an exemplary embodiment of the present inventive concept, the coating layer 110B may cover the inside of the upper penetrating portion UP of each of the plurality of internal gas supply units 116 together.

The coating layer 110B may conformally cover the inside of the lower penetrating portion LP of each of the plurality of injection ports 112 together with the surfaces of the showerhead body 110A including the lower structure 113, the upper structure 114, and the blocker plate 115. However, according to an exemplary embodiment of the present inventive concept, the coating layer 110B may cover and combine the surface of each of the lower structure 113, the upper structure 114, and the blocker plate. For example, the coating layer 110B may be interposed between the lower structure 113, the upper structure 114, and the blocker plate 115.

The showerhead 110 may uniformly supply the process gas introduced into the second internal space IS2 through the gas inlet 111 to the first internal space IS1 through the plurality of internal gas supply units 116, and uniformly supply the process gas introduced into the first internal space IS1 into the process chamber 10 through the plurality of injection ports 112. Accordingly, the showerhead 110 may control the thickness distribution and film quality characteristics of the deposited material by adjusting the uniformity and distribution of the process gas.

According to an exemplary embodiment of the present inventive concept, the gas supply module 100 may further include a high-frequency power source (HFS) connected to the showerhead 110. The process gas introduced into the showerhead 110 through the gas inlet 11 may be converted into a plasma state by high-frequency power generated by the HFS.

According to an exemplary embodiment of the present inventive concept, the gas supply module 100 may further include a low-frequency power source (LFS) connected to the showerhead 110. Mobility of ions of the process gas in the plasma state may be controlled by low-frequency power generated by the LFS.

The insulating member 120 may surround a side surface of the showerhead 110. The insulating member 120 may be disposed between the showerhead body 110A and the process chamber 10. For example, the insulating member 120 may be in contact with the process chamber 10 and the showerhead 110. The insulating member 120 may be in contact with the side surface of the showerhead 110. The insulating member 120 may be in contact with a portion of the process chamber 10, and may be fixed to the showerhead 110. For example, the insulating member 120 may be fixed to the showerhead 110 by an adhesive and/or by being disposed on the process chamber 10. As another example, the insulating member 120 may be fixed to the showerhead 110 by a fastener. The insulating member 120 may protect the process chamber 10 from plasma formed in the internal spaces IS1 and IS2 of the showerhead 110 or insulate the showerhead 110 from the process chamber 10, but the role of the insulating member 120 is not limited thereto. According to an exemplary embodiment of the present inventive concept, the insulating member 120 may be in contact with the side region 113S of the lower structure 113 and separate the side region 113S from the process chamber 10, and the insulating member 120 may surround and/or completely cover a side surface and a bottom surface of the protrusion 113P of the showerhead 110. The insulating member 120 may include a ceramic material, for example, aluminum oxide (Al₂O₃).

The temperature control unit 130 may include a heater for controlling the temperature of the gas supply module 100. For example, the heater may be in contact with the showerhead 110 to control the temperature of the showerhead 110, thereby affecting the temperature of the insulating member 120 that is in contact with the showerhead 110. According to an exemplary embodiment of the present inventive concept, the temperature control unit 130 may further include a temperature measurement sensor, which measures the temperature of the showerhead 110, and a control unit that controls the temperature of the heater.

According to an exemplary embodiment of the present inventive concept, the number of the temperature control units 130 may be plural, and each of heaters of the plurality of temperature control units 130 may be spaced apart from each other and be in contact with the gas supply module 100. The plurality of temperature control units 130 may control the temperature of the gas supply module 100 independently of each other.

The temperature control unit 130 may control the temperature of the showerhead 110 to be substantial constant to control a distribution process performed on the substrate W, and may control the temperature of the showerhead 110 to prevent byproducts from being attached to the showerhead 110. The byproducts may be generated, for example, during a cleaning process for removing particles generated during deposition. Referring to FIG. 1, the byproducts may be formed as the susceptor of the horizontal support 22 reacts with fluorine gas for the cleaning.

In a case where the process is performed in the process chamber 10 while controlling the temperature of the showerhead 110 to a low temperature, for example, about 400° C. or less, the byproducts may be easily attached to the showerhead 110. In the gas supply module 100 according to an exemplary embodiment of the present inventive concept, the temperature control unit 130 may control the temperature of the showerhead 110 to a high temperature, for example, about 400° C. or higher, thereby preventing the byproducts from being attached to the showerhead 110.

Referring to [Table 1] below, the showerhead body 110A includes the metal matrix composite (MMC), and thus may have a coefficient of thermal expansion similar to that of the insulating member 120 including a ceramic material while having thermal conductivity similar to that of a metal material. Accordingly, damage to the insulating member 120 that is in contact with the showerhead 110 may be prevented even in a relatively high-temperature environment.

TABLE 1

| | MMC | | Al | SUS | Ceramics | |
|---|---|---|---|---|---|---|
| Ceramics/Reinforcing material | SiC | SiC | — | — | Al₂O₃ | SiC |
| Metal | Al | Si | — | — | — | — |
| Density(g/cm³) | 2.8 | 3 | 2.7 | 7.9 | 3.9 | 3.1 |
| Young’s Modulus(Mpa) | 125 | 350 | 80 | 210 | 390 | 410 |
| Thermal Expansion(10⁻⁶/K) | 14 | 3 | 20 | 17 | 5 | 3 |
| Thermal Conductivity (W/m * K) | 150 | 170 | 125 | 15 | 30 | 150 |
| Volume Resistivity(Ω * cm) | — | 0.02 | — | — | >10¹⁴ | >10¹⁵ |

By controlling the temperature of the showerhead 110 to the high temperature to prevent attachment of the byproducts and prevent damage to the insulating member 120, maintenance efficiency of the showerhead 110 may be relatively increased. The maintenance efficiency may mean the number of times a process such as deposition that may be performed per cleaning is performed. As the maintenance efficiency increases, the reliability or productivity of the substrate processing apparatus 1 may be increased.

As the showerhead body 110A includes the metal matrix composite (MMC), the temperature of the showerhead body 110A may be kept relatively high without being periodically changed, thereby preventing the coating layer 110B from peeling off.

Further, the showerhead body 110A includes the metal matrix composite (MMC), and thus may have a coefficient of thermal expansion similar to that of the coating layer 110B including aluminum fluoride (AlF) while having thermal conductivity similar to that of a metal material. Accordingly, peeling of the coating layer 110B from the showerhead body 110A may be prevented.

According to an exemplary embodiment of the present inventive concept, the substrate processing apparatus 1 may further include a fastening member 15 that is in contact with the showerhead 110 and the process chamber 10. The fastening member 15 may connect the showerhead 110 and the process chamber 10 to each other. According to an exemplary embodiment of the present inventive concept, an upper surface of the protrusion 113P of the showerhead 110 may be in contact with the process chamber 10, and the fastening member 15 may be disposed between the upper surface of the protrusion 113P and the process chamber 10. For example, the fastening member 15 may connect the process chamber 10 and the upper surface of the protrusion 113P to each other. However, according to an exemplary embodiment of the present inventive concept, a position at which the fastening member 15 is disposed may be variously changed.

According to an exemplary embodiment of the present inventive concept, the gas supply module 100 may further include a sealing member 125 that is in contact with the showerhead 110 and the insulating member 120. The sealing member 125 may connect the showerhead 110 and the insulating member 120 to each other. According to an exemplary embodiment of the present inventive concept, a lower surface of the protrusion 113P of the showerhead 110 may be in contact with the insulating member 120, and the sealing member 125 may be disposed between the insulating member 120 and the lower surface of the protrusion 113P. For example, the sealing member 125 may connect the insulating member 120 and the lower surface of the protrusion 113P to each other. However, according to an exemplary embodiment of the present inventive concept, a position at which the sealing member 125 is disposed may be variously changed. According to an exemplary embodiment of the present inventive concept, at least a portion of the sealing member 125 may be buried in the insulating member 120, and a portion of the sealing member 125 that is not buried in the insulating member 120 may be in contact with the showerhead 110. The sealing member 125 may include, for example, a perfluoroelastomer material.

According to an exemplary embodiment of the present inventive concept, the gas supply module 100 may further include a cooling member 140. For example, the cooling member 140 may disposed in a region adjacent to the fastening member 15 and the sealing member 125; however, the present inventive concept is not limited thereto. The cooling member 140 may prevent characteristics of the fastening member 15 and the sealing member 125 from being deteriorated by heat transferred from the showerhead 110 in a relatively high-temperature environment. According to an exemplary embodiment of the present inventive concept, the cooling member 140 may be disposed in the protrusion 113P of the showerhead 110, but the present inventive concept is not limited thereto.

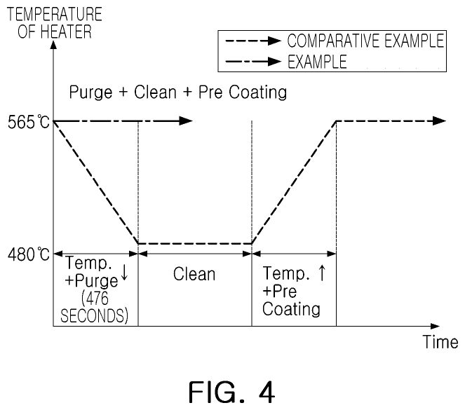

FIG. 4 is a graph for describing a temperature change of the susceptor while the substrate processing apparatus 1, according to an exemplary embodiment of the present inventive concept performs cleaning on the substrate W. Examples of the present disclosure, in which the coating layer 110B is included, and a comparative example, in which the coating layer 110B is not included, will be described and compared with reference to FIGS. 1 through 3.

Referring to FIGS. 1 through 3, the gas supply module 100 according to an exemplary embodiment of the present inventive concept includes the coating layer 110B surrounding at least one surface of the showerhead body 110A, and thus adsorption of the byproducts, which are generated from the cleaning of the substrate W, on the showerhead 110 may be prevented. The byproducts may be generated as the susceptor of the horizontal support 22 including aluminum nitride (AlN) is combined with the fluorine gas during the cleaning. As the byproducts are attached to the plurality of injection ports 112 of the showerhead 110, an injection rate of the showerhead 110 may be changed. The byproducts may be generated more as the temperature of the susceptor increases.

Referring to the comparative example of the showerhead without the coating layer 110B, a section for decreasing and increasing the temperature of the susceptor may be included to reduce the byproducts generated in the cleaning. Accordingly, the productivity of the substrate processing apparatus may be decreased due to the time from the section for decreasing and increasing the temperature.

Referring to the showerhead 110, according to an exemplary embodiment of the present inventive concept, in which the coating layer 110B is included, the section for decreasing and increasing the temperature of the susceptor, which is included in the comparative example, may be removed and the temperature may be maintained to be substantially constant during the cleaning. This may be because the coating layer 110B may prevent the byproducts from being attached to the showerhead 110 irrespective of the amount of the byproducts generated. Accordingly, the productivity of the substrate processing apparatus 1 according to an exemplary embodiment of the present inventive concept may be relatively higher than that of the substrate processing apparatus according to the comparative example.

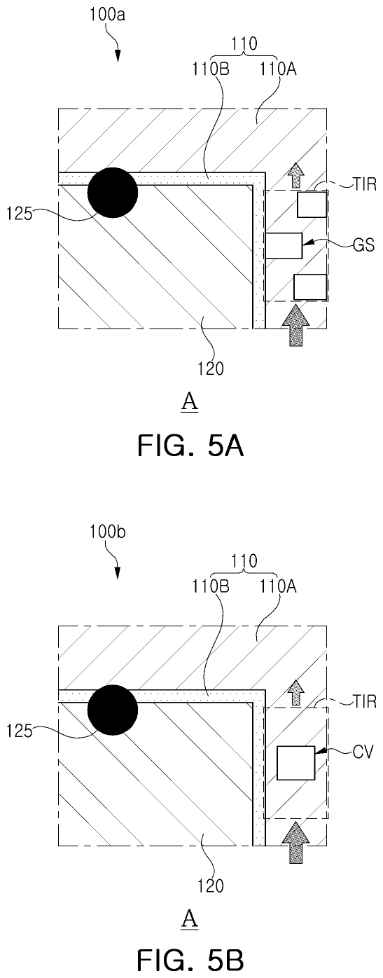

FIGS. 5A and 5B are partially enlarged cross-sectional views of modified examples of the gas supply module according to an exemplary embodiment of the present inventive concept of FIG. 3. FIGS. 5A and 5B illustrate enlarged cross sectional views of a region “A” of FIG. 3.

Referring to FIGS. 3 and 5A, in a gas supply module 100a according to an exemplary embodiment of the present inventive concept, the showerhead 110 may have a thermal isolation region TIR. The thermal isolation region TIR may be a portion of the showerhead 110 and may be a portion having a structure different from that of an adjacent region. The showerhead 110 may have a portion having a smaller width in the thermal isolation region TIR than in regions adjacent to the thermal isolation region TIR. According to an exemplary embodiment of the present inventive concept, the showerhead 110 may have an empty groove structure in the thermal isolation region TIR.

According to an exemplary embodiment of the present inventive concept, the thermal isolation region TIR may be disposed in the side region 113S of the showerhead 110. The showerhead 110 may have a portion having a smaller width in the thermal isolation region TIR than in other portions of the side region 113S adjacent to the thermal isolation region TIR. The thermal isolation region TIR may have a groove structure GS in which a groove is formed inwardly with respect to a portion of the side region 113S and is recessed toward an inner side of the side region 113S. For example, the groove of the groove structure GS may face the insulating member 120. According to an exemplary embodiment of the present inventive concept, the groove structure GS may include a plurality of groove structures GS, and at least some of the plurality of groove structures GS may be in contact with the insulating member 120 or the like and have an empty space or be filled with air.

The thermal isolation region TIR may be disposed in a region between a portion of the showerhead 110 that is in contact with the temperature control unit 130 and a portion of the showerhead 110 that is in contact with the sealing member 125 or the fastening member 15. According to an exemplary embodiment of the present inventive concept, the thermal isolation region TIR may be disposed in a region adjacent to the protrusion 113P of the showerhead 110. The thermal isolation region TIR may reduce heat transferred to the sealing member 125 and the fastening member 15 in the showerhead 110 that is maintained in a high-temperature environment by the temperature control unit 130 to thereby increase reliability and prevent deterioration of the substrate processing apparatus 1. The thermal isolation region TIR of the showerhead 110 may serve to control heat transferred to the sealing member 125 and the fastening member 15 together with the cooling member 140 illustrated in FIG. 3.

Referring to FIGS. 3 and 5B, a gas supply module 100b according to an exemplary embodiment of the present inventive concept may have a thermal isolation region TIR having a structure different from that of FIG. 5A.

In the gas supply module 100b according to an exemplary embodiment of the present inventive concept, the showerhead 110 may have a portion having a smaller width in the thermal isolation region TIR than in regions adjacent to the thermal isolation region TIR. The showerhead 110 may have one or more cavities CV disposed inside the thermal isolation region TIR of the showerhead 100. The cavity CV may have an empty space or may be filled with air. The thermal isolation region TIR may be formed by brazing or bonding upper and lower insulating members having a groove structure together, but the present inventive concept is not limited thereto. Heat generated from the temperature control unit 130 and transferred to the sealing member 125 and the fastening member 15 through the showerhead 110 may be reduced by the thermal isolation region TIR including the cavity CV. Accordingly, deterioration of the characteristics of the sealing member 125 and the fastening member 15 may be prevented.

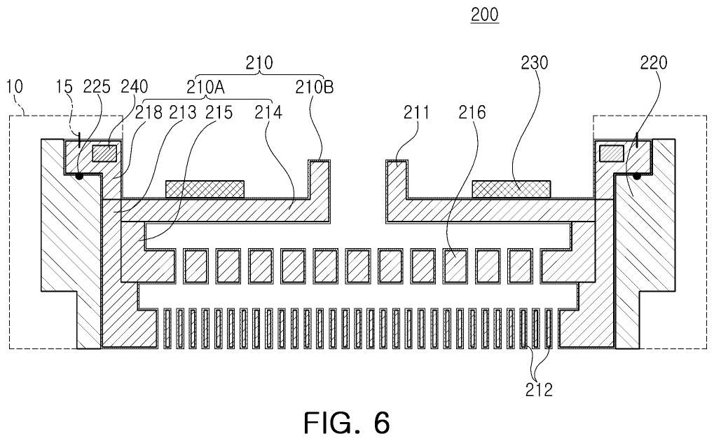

FIG. 6 is a schematic cross-sectional view illustrating a gas supply module 200 and a portion of a process chamber 10 adjacent thereto according to an exemplary embodiment of the present inventive concept.

Referring to FIG. 6, the gas supply module 200 may include a showerhead 210, an insulating member 220, and a temperature control unit 230.

The gas supply module 200 according to an exemplary embodiment of the present inventive concept may have the same structure as that described in FIG. 3, except for a structure of the showerhead 210.

The showerhead 210 may include a showerhead body 210A and a coating layer 210B covering the showerhead body 210A. The showerhead body 210A may include first showerhead bodies 213, 214, and 215 including a metal matrix composite (MMC) and a second showerhead 218 including a metal material, for example, aluminum (Al). According to an exemplary embodiment of the present inventive concept, the second showerhead body 218 may include two or more metal elements. The first showerhead bodies 213, 214, and 215 and the second showerhead body 218 may be in contact with each other, and the coating layer 210B may cover the first showerhead bodies 213, 214, and 215 and the second showerhead body 218.

According to an exemplary embodiment of the present inventive concept, in the second showerhead body 218, a metal matrix composite (MMC) of a region including a region corresponding to the protrusion 113P in the description of FIG. 3 may be substituted with a metal, but the arrangement relationship and size of the second showerhead body 218 are not limited thereto. According to an exemplary embodiment of the present inventive concept, in the second showerhead body 218, a portion of a lower structure 213, an upper structure 214, or a blocker plate 215 may be substituted with a metal, and a plurality of portions may be spaced apart from each other. For example, in the showerhead body 210A, a portion including the metal matrix composite (MMC) and a portion including the metal may be variously changed in consideration of a distance to the insulating member 220, a sealing member 225, a fastening member 15, or the like, a difference in coefficient of thermal expansion, a difference in thermal conductivity, and the like.

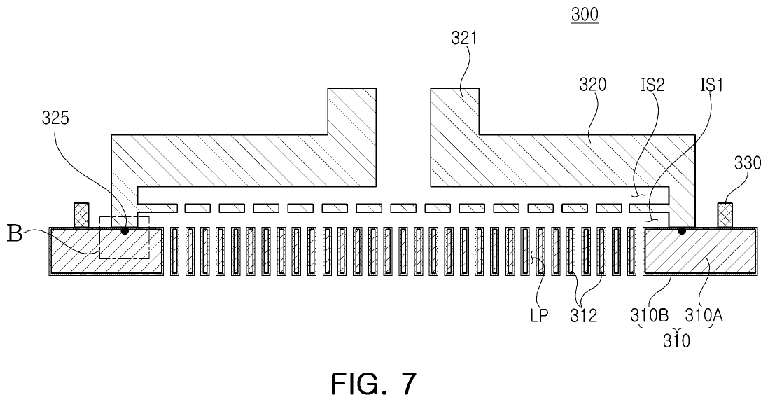

FIG. 7 is a schematic cross-sectional view illustrating a gas supply module 300 according to an exemplary embodiment of the present inventive concept.

The gas supply module 300 may include a showerhead 310, a gas introduction member 320, and a temperature control unit 330.

The showerhead 310 may include a showerhead body 310A and a coating layer 310B covering the showerhead body 310A. According to an exemplary embodiment of the present inventive concept, in a case where a plurality of injection ports 312 are holes penetrating through the showerhead body 310A, the coating layer 310B may conformally cover the inside of the holes. The showerhead body 310A may include a metal matrix composite (MMC). According to an exemplary embodiment of the present inventive concept, the showerhead body 310A may include a matrix metal such as aluminum (Al) and a ceramic filler such as silicon carbide (SiC). The coating layer 310B may include aluminum fluoride (AlF). According to an exemplary embodiment of the present inventive concept, the coating layer 310B may further include a material having etch resistance, such as yttrium oxide (Y₂O₃). According to an exemplary embodiment of the present inventive concept, the coating layer 310B may further include two or more materials having etch resistance.

The showerhead body 310A may have a plate structure having the plurality of injection ports 312. For example, the showerhead body 310A may have a cylindrical shape with the plurality of injection ports 312; however, the present inventive concept is not limited to that shape. Each of the plurality of injection ports 312 may have a lower penetrating portion LP penetrating through the showerhead body 310A. According to an exemplary embodiment of the present inventive concept, the lower penetrating portion LP may be a circular hole, and the plurality of injection ports 312 may be arranged at a predetermined interval along a circumference of a circle having a constant diameter in the showerhead body 310A. For example, from a plan view, the showerhead body 310A may have a circular shape. However, the shape of the lower penetrating portion LP and the arrangement relationship of the plurality of injection ports 312 are not limited thereto and may be variously changed.

The coating layer 310B may conformally cover a surface of the showerhead body 310A and the inside of the lower penetrating portion LP.

The gas introduction member 320 may include a gas inlet 321 through which the process gas is introduced. The process gas may include one or more source gases. The gas introduction member 320 may be in contact with an upper surface of the showerhead 310 to provide an internal space into which the process gas is introduced. According to an exemplary embodiment of the present inventive concept, the internal space may be a first internal space IS1 and a second internal space IS2. The first internal space IS1 may be adjacent to the showerhead body 310A and the injection ports 312, and the second internal space IS2 may overlap the first internal space IS1, however, the present inventive concept is not limited thereto. For example, the internal space IS1 and the second internal space IS2 may be defined by internal passages of the gas introduction member 320, but the present inventive concept is not limited thereto. The gas introduction member 320 may include a metal material, for example, aluminum (Al).

The temperature control unit 330 may include a heater for controlling the temperature of the gas supply module 300. The heater may be in contact with the showerhead 310 and control the temperature of the showerhead 310. According to an exemplary embodiment of the present inventive concept, the temperature control unit 330 may further include a temperature measurement sensor and a control unit. The temperature measurement sensor measures the temperature of the showerhead 310 that is controlled by the heater, and the control unit controls the temperature of the heater.

According to an exemplary embodiment of the present inventive concept, the number of the temperature control units 330 may be plural, and each of heaters of the plurality of temperature control units 330 may be spaced apart from each other and be in contact with the gas supply module 300. The plurality of temperature control units 330 may control the temperature of the gas supply module 300 independently of each other.

The temperature control unit 330 may control the temperature of the showerhead 310 to be substantially constant to control distribution of the process performed on the substrate W, and may control the temperature of the showerhead 310 to prevent byproducts from being attached to the showerhead 310.

According to an exemplary embodiment of the present inventive concept, the gas supply module 300 may further include a sealing member 325 that is in contact with the showerhead 310 and the gas introduction member 320. The sealing member 325 may connect the showerhead 310 and the gas introduction member 320 to each other. In an exemplary embodiment of the present inventive concept, the sealing member 325 may be in contact with the upper surface of the showerhead 310 and a lower surface of the gas introduction member 320 in an outer periphery region of the showerhead body 310A. For example, the sealing member 325 may be in an outer periphery region of a region in which the plurality of injection ports 312 are disposed. For example, the plurality of injection ports 312 may be between the sealing member 325. However, according to an exemplary embodiment of the present inventive concept, a position at which the sealing member 325 is disposed may be variously changed. According to an exemplary embodiment of the present inventive concept, at least a portion of the sealing member 325 may be buried in the showerhead 310, and a portion of the sealing member 325 that is not buried in the showerhead 310 may be in contact with the gas introduction member 320.

Referring to FIGS. 7 and 4, as the showerhead 310 includes the coating layer 310B, a section for decreasing and increasing the temperature of the susceptor may be removed and the temperature may be maintained constant during the cleaning. Further, the showerhead 310 includes the metal matrix composite (MMC), and thus may have a coefficient of thermal expansion similar to that of the coating layer 310B including aluminum fluoride (AlF) while having thermal conductivity similar to that of a metal material. Accordingly, peeling of the coating layer 310B from the showerhead body 310A may be prevented.

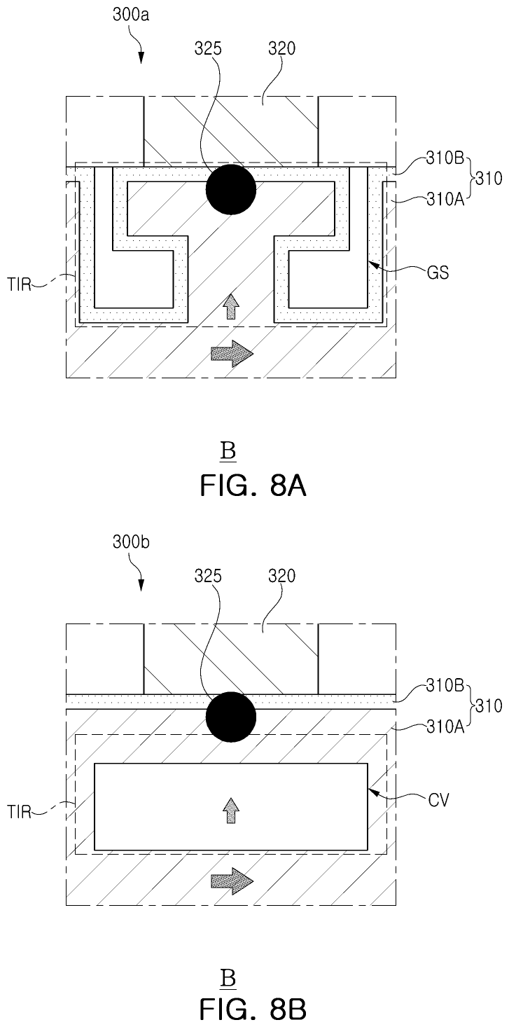

FIGS. 8A and 8B are partially enlarged cross-sectional views of modified examples of the gas supply module according to an exemplary embodiment of the present inventive concept, of FIG. 7. FIGS. 8A and 8B illustrate cross sections of a region “B” of FIG. 7.

Referring to FIGS. 7 and 8A, in a gas supply module 300a according to an exemplary embodiment of the present inventive concept, the showerhead 310 may have a thermal isolation region TIR. The thermal isolation region TIR may be a portion of the showerhead 310 and may be a portion having a structure different from that of an adjacent region in the showerhead 310. The showerhead 310 may have an empty groove structure in the thermal isolation region TIR.

According to an exemplary embodiment of the present inventive concept, the thermal isolation region TIR may have a groove structure GS in which a groove is formed toward an inner side or inner region of the showerhead 310 and recessed inwardly from the upper surface of the showerhead 310. The groove structure GS may have an annular shape surrounding a portion of the showerhead 310. According to an exemplary embodiment of the present inventive concept, the groove structure GS may have an empty space or may be filled with air.

The thermal isolation region TIR may be disposed in a region between a portion of the showerhead 310, which is in contact with the temperature control unit 330, and a portion of the showerhead 310 that is in contact with the sealing member 325. According to an exemplary embodiment of the present inventive concept, the thermal isolation region TIR may be positioned in an inner region of the showerhead 310 that vertically overlaps with a region where the gas introduction member 320 and the showerhead 310 are in contact with each other. For example, the thermal isolation region TIR may vertically overlap the sealing member 325. The thermal isolation region TIR may significantly reduce heat transferred to the sealing member 325 in the showerhead 310 maintained in a relatively high-temperature environment by the temperature control unit 330 to thereby increase reliability and prevent deterioration of the substrate processing apparatus 1.

Referring to FIGS. 7 and 8B, a gas supply module 300b according to an exemplary embodiment of the present inventive concept may have a thermal isolation region TIR having a structure different from that of FIG. 8A.

In the gas supply module 300b according to an exemplary embodiment of the present inventive concept, the showerhead 310 may have an empty groove structure in the thermal isolation region TIR.

According to an exemplary embodiment of the present inventive concept, the showerhead 310 may have one or more cavities CV disposed in the thermal isolation region TIR. The cavity CV may be an empty space or may be a space filled with air. The cavity CV may be formed by brazing or bonding the lower surface of the gas introduction member 320, which has the groove structure, and the upper surface of the showerhead 310, which has the groove structure, to each other, but the present inventive concept is not limited thereto. Heat transferred from the showerhead 310 to the sealing member 325 may be reduced by the cavity CV, and accordingly, deterioration of the characteristic of the sealing member 325 may be prevented.

As set forth above, according to an exemplary embodiment of the present inventive concept, the substrate processing apparatus that includes a gas supply module including a metal matrix composite (MMC) to increase reliability at a relatively high temperature and prevent the coating layer from peeling off may be provided.

According to an exemplary embodiment of the present inventive concept, the substrate processing apparatus that includes the gas supply module including the coating layer to prevent adsorption of byproducts and improve thickness distribution may be provided.

While the present inventive concept has been particularly shown and described with reference to example embodiments thereof, it will be apparent to those of ordinary skill in the art that various changes in form and detail may be made thereto without departing from the spirit and scope of the present inventive concept

What is claimed is:

1. A substrate processing apparatus comprising:
a process chamber;
a substrate support structure disposed at a lower portion of the process chamber and configured to accommodate a substrate; and
a gas supply module disposed at an upper portion of the process chamber and supplying a process gas to the substrate,
wherein the gas supply module includes a showerhead that includes:
a first showerhead body including a plurality of injection ports configured to transfer gas transferred from a gas inlet into the process chamber; and
a coating layer covering the first showerhead body and including aluminum fluoride, wherein the first showerhead body includes a metal matrix composite (MMC).

2. The substrate processing apparatus of claim 1, wherein the coating layer further includes yttrium oxide.

3. The substrate processing apparatus of claim 1, wherein the gas supply module further includes a temperature control unit configured to control a temperature of the gas supply module and including a heater, and
the temperature control unit is disposed on the showerhead.

4. The substrate processing apparatus of claim 3, wherein the temperature control unit includes a plurality of temperature control units,
the plurality of temperature control units are spaced apart from each other and are each disposed on the gas supply module, and
the plurality of temperature control units control the temperature of the gas supply module independently of each other.

5. The substrate processing apparatus of claim 1, wherein the gas supply module further includes an insulating member disposed between the showerhead and the process chamber.

6. The substrate processing apparatus of claim 5, wherein the insulating member is in contact with the process chamber and the showerhead.

7. The substrate processing apparatus of claim 6, further comprising:
a temperature control unit configured to control a temperature of the gas supply module and disposed on the showerhead; and
a sealing member connecting the insulating member and the showerhead to each other.

8. The substrate processing apparatus of claim 7, wherein the sealing member is disposed adjacent to the temperature control unit,
the showerhead has a thermal isolation region positioned between a first portion of the first showerhead body and a second portion of the first showerhead body, wherein the first portion is in contact with the temperature control unit, and the second portion is in contact with the sealing member, and
the showerhead has a portion in the thermal isolation region that has a smaller width than that of regions of the showerhead adjacent to the thermal isolation region.

9. The substrate processing apparatus of claim 8, wherein the showerhead has one or more grooves in the thermal isolation region.

10. The substrate processing apparatus of claim 8, wherein the showerhead has one or more cavities disposed inside the showerhead in the thermal isolation region.

11. The substrate processing apparatus of claim 1, wherein the showerhead further includes a second showerhead body disposed on the first showerhead body and including a metal material, and
the coating layer covers the first showerhead body and the second showerhead body.

12. The substrate processing apparatus of claim 11, wherein the second showerhead body includes two or more metal elements.

13. A substrate processing apparatus comprising:
a process chamber;
a substrate support structure disposed at a first portion of the process chamber and configured to accommodate a substrate; and
a gas supply module disposed at a second portion of the process chamber and supplying a process gas to the substrate,
wherein the gas supply module includes:
a showerhead including a showerhead body and a coating layer, wherein the showerhead body includes a gas inlet and a plurality of injection ports configured to transfer the process gas transferred from the gas inlet into the process chamber, and wherein the coating layer covers the showerhead body;
an insulating member disposed between the showerhead and the process chamber; and
a temperature control unit controlling a temperature of the gas supply module,
the showerhead has a first region in which the plurality of injection ports are disposed and a second region extending from the first region,
the insulating member is disposed on the second region and separates the second region from the process chamber, and
the showerhead body includes a metal matrix composite (MMC).

14. The substrate processing apparatus of claim 13, wherein the substrate support structure includes a horizontal support including a susceptor,
wherein the susceptor includes aluminum nitride, and
the coating layer includes aluminum fluoride.

15. The substrate processing apparatus of claim 13, wherein each of the plurality of injection ports includes a hole penetrating through the first region of the showerhead, and
the coating layer conformally covers an inside of the hole.

16. The substrate processing apparatus of claim 13, wherein the showerhead has a protrusion extending in a horizontal direction from the second region toward the process chamber.

17. The substrate processing apparatus of claim 16, further comprising:
a sealing member disposed between a lower surface of the protrusion and the insulating member; and
a fastening member disposed between an upper surface of the protrusion and the process chamber,
wherein the lower surface of the protrusion is in contact with the insulating member, and the upper surface of the protrusion is in contact with the process chamber.

18. The substrate processing apparatus of claim 16, wherein the showerhead has a thermal isolation region positioned in at least a part of the second region adjacent to the protrusion, and
the showerhead has a groove structure in the thermal isolation region.

19. A substrate processing apparatus comprising:
a process chamber;
a substrate support structure disposed at a lower portion of the process chamber and configured to accommodate a substrate; and
a gas supply module disposed at an upper portion of the process chamber and supplying a process gas to the substrate,
wherein the gas supply module includes:
a showerhead including a plurality of injection ports configured to transfer gas, which is transferred from a gas inlet, into a process chamber; and
a temperature control unit controlling a temperature of the showerhead,
wherein the showerhead includes a showerhead body and a coating layer, wherein the showerhead body includes a metal matrix composite (MMC), and the coating layer covers the showerhead body and includes aluminum fluoride.

20. The substrate processing apparatus of claim 19, wherein each of the plurality of injection ports includes a hole penetrating through a lower region of the showerhead, and
the coating layer covers the hole.
